(19) United States
(12) Patent Application Publication
(10) Pub. No.: US 2026/0088763 A1
(43) Pub. Date: Mar. 26, 2026

(54) LOAD MODULATED POWER AMPLIFIERS WITH PHASE COMPENSATION

(71) Applicant: Skyworks Solutions, Inc., Irvine, CA (US)

(72) Inventors: Kunal Datta, Sunnyvale, CA (US); Srivatsan Jayaraman, Santa Clara, CA (US)

(21) Appl. No.: 19/332,570

(22) Filed: Sep. 18, 2025

Related U.S. Application Data
(60) Provisional application No. 63/696,978, filed on Sep. 20, 2024.

(51) Int. Cl. H03F 1/02; H03F 1/32; H03F 3/24; H04B 1/04; H04B 1/40

(52) U.S. Cl. CPC H03F 1/02; H03F 1/32; H03F 3/24; H04B 1/04; H04B 1/40; H03F 2200/213; H03F 2200/451; H03F 2200/537; H03F 2201/3212; H04B 2001/0408

(57) ABSTRACT

Load modulated power amplifiers with phase compensation are disclosed herein. In certain embodiments, a load modulated power amplifier includes a load modulation capacitor, a pair of amplifiers, an output balun having a primary winding connected between the outputs of the pair of amplifiers and a secondary winding connected between an output terminal and the load modulation capacitor, and a load modulation control amplifier that controls a capacitance value of the load modulation capacitor based on an envelope of a radio frequency (RF) signal received at an input terminal to the load modulated power amplifier. The load modulated power amplifier further includes a phase modulation capacitor connected along an RF signal path between the input terminal and the output terminal and a phase modulation control amplifier that controls a capacitance value of the phase modulation capacitor to provide phase compensation.

### CROSS-REFERENCE TO RELATED APPLICATIONS

This application claims the benefit of priority under 35 U.S.C. § 119 of U.S. Provisional Patent Application No. 63/696,978, filed Sep. 20, 2024, and titled “LOAD MODULATED POWER AMPLIFIERS WITH PHASE COMPENSATION,” which is herein incorporated by reference in its entirety.

### BACKGROUND

### Field

Embodiments of the invention relate to electronic systems, and more particularly to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and wearable electronics.

### SUMMARY

In one aspect, a mobile device includes a transceiver configured to generate a radio frequency signal, and a front-end system including a load modulated power amplifier having an input terminal configured to receive the radio frequency signal and an output terminal configured to provide an amplified radio frequency signal. The load modulated power amplifier includes a load modulation capacitor, a first amplifier, a second amplifier, an output balun having a first winding electrically connected between an output of the first amplifier and an output of the second amplifier and a second winding electrically connected between the output terminal and the load modulation capacitor, a load modulation control amplifier configured to control a capacitance value of the load modulation capacitor based on an envelope of the radio frequency signal, a phase modulation capacitor connected along a radio frequency signal path between the input terminal and the output terminal, and a phase modulation control amplifier configured to control a capacitance value of the phase modulation capacitor to provide phase compensation.

In various embodiments, the load modulation control amplifier increases the capacitance value of the load modulation capacitor in response to an increase in a power level of the radio frequency signal, and the phase modulation control amplifier decreases the capacitance value of the phase modulation capacitor in response to the increase in the power level.

In some embodiments, the load modulation control amplifier and the phase modulation control amplifier are controlled based on the envelope of the radio frequency signal, the phase modulation control amplifier providing an inversion relative to the load modulation control amplifier. According to a number of embodiments, the load modulation control amplifier and the phase modulation control amplifier are each differential-to-single ended amplifiers receiving a differential envelope signal indicating the envelope of the radio frequency signal. In accordance with several embodiments, the transceiver is configured to generate the envelope signal.

In various embodiments, a control voltage outputted from the load modulation control amplifier monotonically increases with a power level of the radio frequency signal, and a control voltage outputted from the phase modulation control amplifier monotonically decreases with the power level of the radio frequency signal.

In some embodiments, the load modulated power amplifier further includes a driver amplifier and an input balun having a first winding electrically connected to an output of the driver amplifier and a second winding electrically connected between an input of the first amplifier and an input of the second amplifier. According to a number of embodiments, the phase modulation capacitor is electrically connected between an output of the driver amplifier and a reference voltage. In accordance with several embodiments, the phase modulation capacitor is electrically connected between an input of the driver amplifier and a reference voltage.

In various embodiments, the phase modulation capacitor is electrically connected to at least one of an input of the first amplifier or an input of the second amplifier.

In several embodiments, the phase modulation capacitor is electrically connected to at least one of the output of the first amplifier or the output of the second amplifier.

In some embodiments, the phase modulation capacitor is electrically connected to the second winding of the output balun.

In various embodiments, the first amplifier and the amplifier are arranged as a pair of amplifiers in a push-pull configuration.

In certain embodiments, the present disclosure relates to a load modulated power amplifier. The load modulated power amplifier includes an input terminal configured to receive a radio frequency signal and an output terminal configured to provide an amplified radio frequency signal, a load modulation capacitor, a pair of amplifiers including a first amplifier and a second amplifier, an output balun having a first winding electrically connected between an output of the first amplifier and an output of the second amplifier and a second winding electrically connected between the output terminal and the load modulation capacitor, a load modulation control amplifier configured to control a capacitance value of the load modulation capacitor based on an envelope of the radio frequency signal, a phase modulation capacitor connected along a radio frequency signal path between the input terminal and the output terminal, and a phase modulation control amplifier configured to control a capacitance value of the phase modulation capacitor to provide phase compensation.

In various embodiments, the load modulation control amplifier increases the capacitance value of the load modulation capacitor in response to an increase in a power level of the radio frequency signal, and the phase modulation control amplifier decreases the capacitance value of the phase modulation capacitor in response to the increase in the power level.

In several embodiments, the load modulation control amplifier and the phase modulation control amplifier are controlled based on the envelope of the radio frequency signal, the phase modulation control amplifier providing an inversion relative to the load modulation control amplifier. According to a number of embodiments, the load modulation control amplifier and the phase modulation control amplifier are each differential-to-single ended amplifiers receiving a differential envelope signal indicating the envelope of the radio frequency signal.

In various embodiments, a control voltage outputted from the load modulation control amplifier monotonically increases with a power level of the radio frequency signal, and a control voltage outputted from the phase modulation control amplifier monotonically decreases with the power level of the radio frequency signal.

In some embodiments, the load modulated power amplifier further includes a driver amplifier and an input balun having a first winding electrically connected to an output of the driver amplifier and a second winding electrically connected between an input of the first amplifier and an input of the second amplifier. According to various embodiments, the phase modulation capacitor is electrically connected between an output of the driver amplifier and a reference voltage. In accordance with a number of embodiments, the phase modulation capacitor is electrically connected between an input of the driver amplifier and a reference voltage.

In several embodiments, the phase modulation capacitor is electrically connected to at least one of an input of the first amplifier or an input of the second amplifier.

In various embodiments, the phase modulation capacitor is electrically connected to at least one of the output of the first amplifier or the output of the second amplifier.

In some embodiments, the phase modulation capacitor is electrically connected to the second winding of the output balun.

In several embodiments, the first amplifier and the amplifier are arranged as a pair of amplifiers in a push-pull configuration.

In certain embodiments, the present disclosure relates to a method of amplification in a load modulated power amplifier, the method includes receiving a radio frequency signal at an input terminal and outputting an amplified radio frequency signal from an output terminal. The method further includes controlling a capacitance value of a load modulation capacitor coupled to an output balun based on an envelope of the radio frequency signal using a load modulation control amplifier, the output balun having a first winding electrically connected between an output of a first amplifier and an output of a second amplifier and a second winding electrically connected between the output terminal and the load modulation capacitor. The method further includes controlling a capacitance value of a phase modulation capacitor to provide phase compensation using a phase modulation control amplifier, the phase modulation capacitor connected along a radio frequency signal path between the input terminal and the output terminal.

In various embodiments, the method further includes using the load modulation control amplifier to increase the capacitance value of the load modulation capacitor in response to an increase in a power level of the radio frequency signal, and using the phase modulation control amplifier to decrease the capacitance value of the phase modulation capacitor in response to the increase in the power level.

In some embodiments, the load modulation control amplifier and the phase modulation control amplifier are controlled based on the envelope of the radio frequency signal, the phase modulation control amplifier providing an inversion relative to the load modulation control amplifier. According to a number of embodiments, the load modulation control amplifier and the phase modulation control amplifier are each differential-to-single ended amplifiers receiving a differential envelope signal indicating the envelope of the radio frequency signal.

In various embodiments, a control voltage outputted from the load modulation control amplifier monotonically increases with a power level of the radio frequency signal, and a control voltage outputted from the phase modulation control amplifier monotonically decreases with the power level of the radio frequency signal.

In some embodiments, the method further includes providing the radio frequency signal to an input of a driver amplifier, and providing single-end to differential signal conversion using an input balun having a first winding electrically connected to an output of the driver amplifier and a second winding electrically connected between an input of the first amplifier and an input of the second amplifier. According to a number of embodiments, the phase modulation capacitor is electrically connected between an output of the driver amplifier and a reference voltage. In accordance with several embodiments, the phase modulation capacitor is electrically connected between an input of the driver amplifier and a reference voltage.

In various embodiments, the phase modulation capacitor is electrically connected to at least one of an input of the first amplifier or an input of the second amplifier.

In several embodiments, the phase modulation capacitor is electrically connected to at least one of the output of the first amplifier or the output of the second amplifier.

In some embodiments, the phase modulation capacitor is electrically connected to the second winding of the output balun.

In several embodiments, the first amplifier and the amplifier are arranged as a pair of amplifiers in a push-pull configuration.

### BRIEF DESCRIPTION OF THE DRAWINGS

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4 is a schematic diagram of an example dual connectivity network topology.

FIG. 5 is a schematic diagram of a load modulated power amplifier with phase compensation according to one embodiment.

FIG. 6A is a schematic diagram of a load modulated power amplifier with phase compensation according to another embodiment.

FIG. 6B is a graph of one example of control voltage for a load modulation capacitor versus output power.

FIG. 6C is a graph of one example of control voltage for a phase modulation capacitor versus output power.

FIG. 7A is a graph of one example of phase versus output power for a load modulated power amplifier without phase compensation.

FIG. 7B is a graph of one example of phase distortion versus output power for a load modulated power amplifier without phase compensation.

FIG. 7C is a graph of one example of phase versus output power for a load modulated power amplifier with phase compensation.

FIG. 7D is a graph of one example of phase distortion versus output power for a load modulated power amplifier with phase compensation.

FIG. 7E is a comparison of the phase distortion characteristics of FIGS. 7B and 7D.

FIG. 7F is a graph of one example of a comparison of spectral emissions (SEM) versus output power for a load modulated power amplifier with and without phase compensation.

FIG. 8A is a schematic diagram of a load modulated power amplifier with phase compensation according to another embodiment.

FIG. 8B is a schematic diagram of a load modulated power amplifier with phase compensation according to another embodiment.

FIG. 9 is a schematic diagram of a load modulated power amplifier with phase compensation according to another embodiment.

FIG. 10 is a schematic diagram of a load modulated power amplifier with phase compensation according to another embodiment.

FIG. 11 is a schematic diagram of a load modulated power amplifier with phase compensation according to another embodiment.

FIG. 12 is a schematic diagram of one embodiment of a mobile device.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

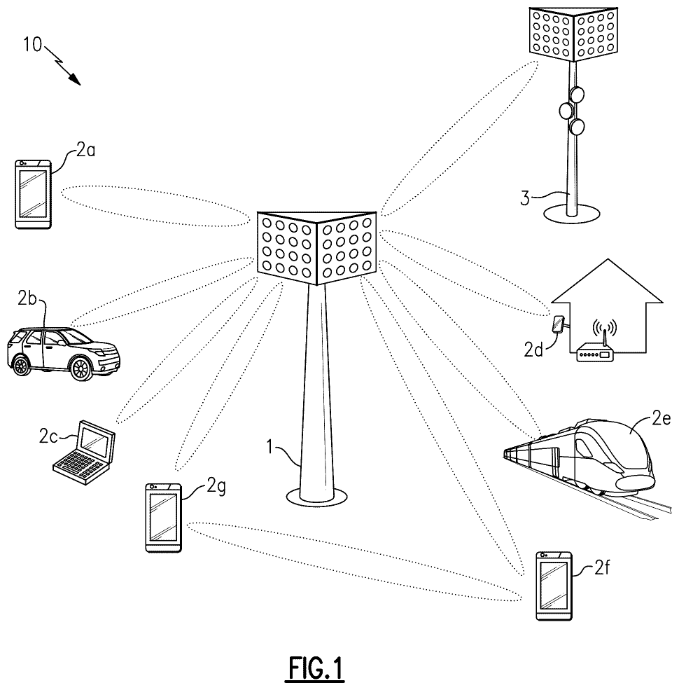

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHZ), FR2-2 (52 GHz to 71 GHZ), and/or FR1 (400 MHz to 7125 MHZ).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refer to technology for communication with very low latency, for instance, less than 2 milliseconds. uRLLC can be used for mission-critical communications such as for autonomous driving and/or remote surgery applications. Massive machine-type communications (mMTC) refer to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

In certain implementations, the communication network 10 supports supplementary uplink (SUL) and/or supplementary downlink (SDL). For example, when channel conditions are good, the communication network 10 can direct a particular UE to transmit using an original uplink frequency, while when channel condition is poor (for instance, below a certain criteria) the communication network 10 can direct the UE to transmit using a supplementary uplink frequency that is lower than the original uplink frequency. Since cell coverage increases with lower frequency, communication range and/or signal-to-noise ratio (SNR) can be increased using SUL. Likewise, SDL can be used to transmit using an original downlink frequency when channel conditions are good, and to transmit using a supplementary downlink frequency when channel conditions are poor.

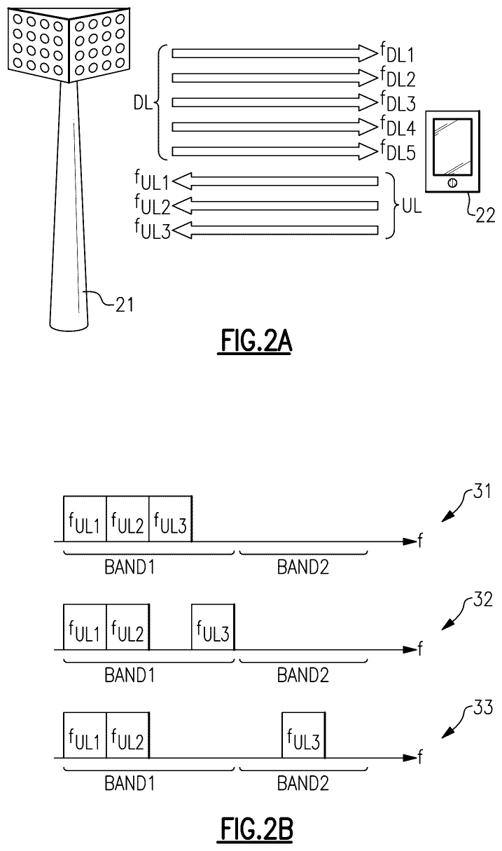

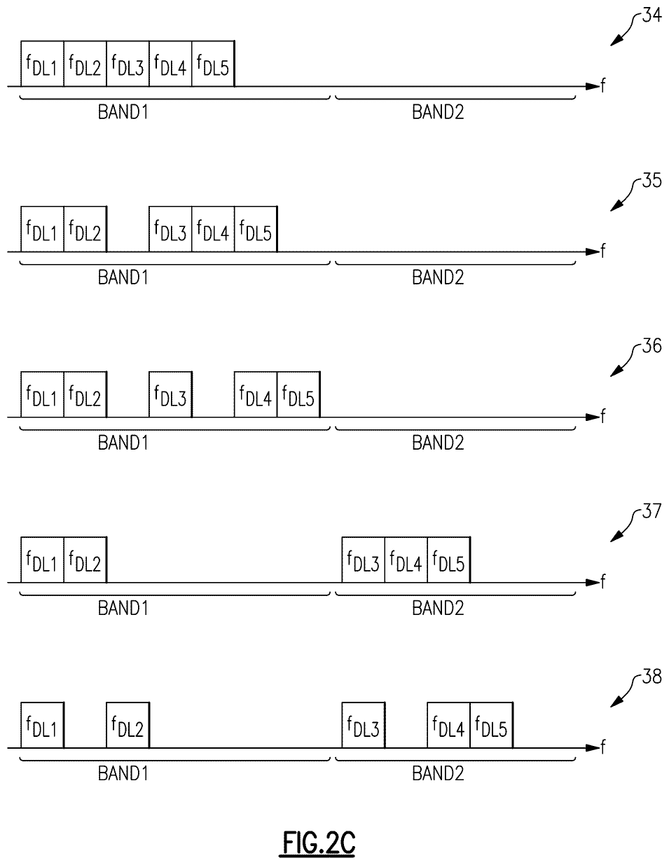

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

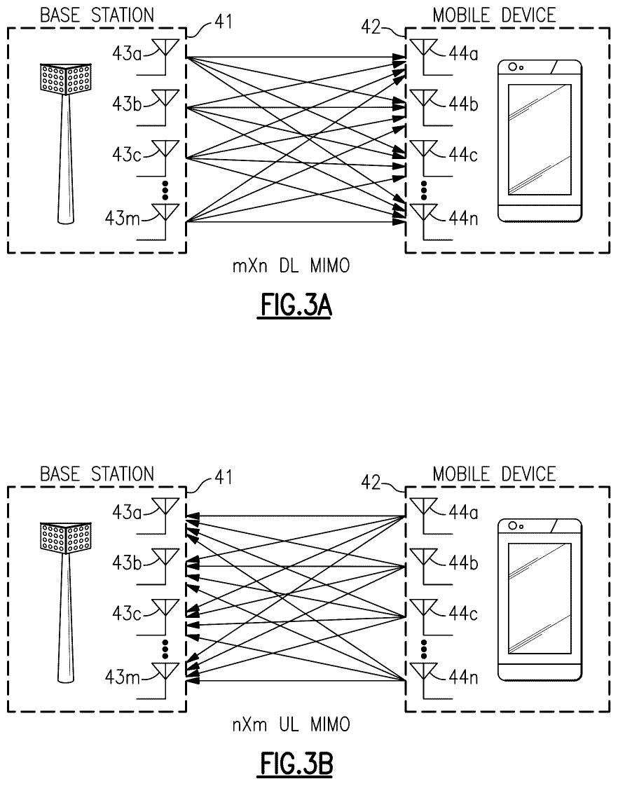

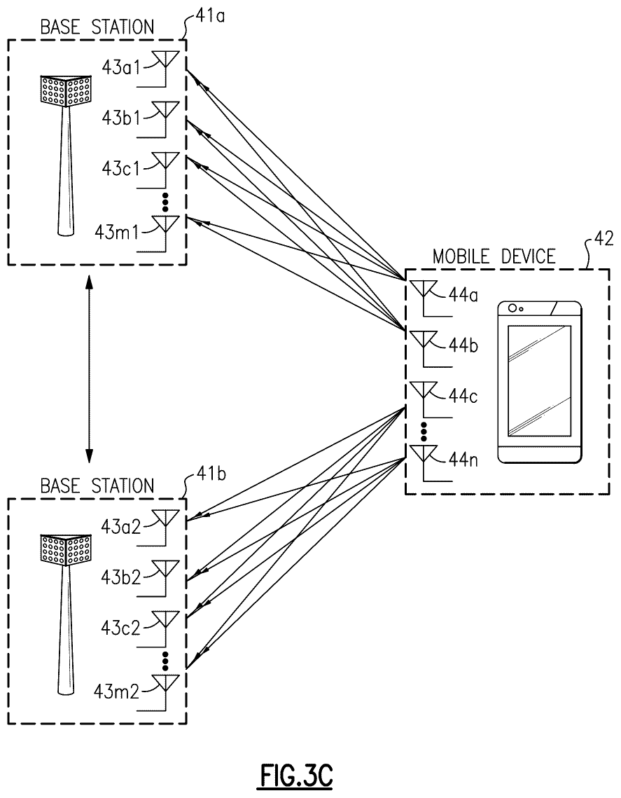

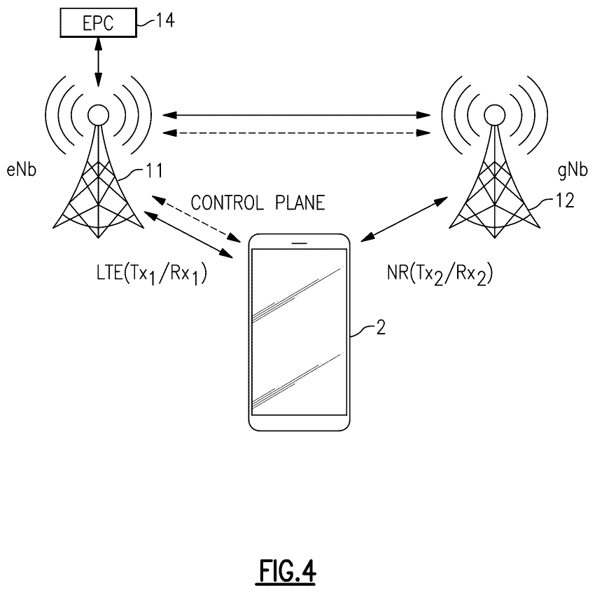

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

With the introduction of the 5G NR air interface standards, 3GPP has allowed for the simultaneous operation of 5G and 4G standards in order to facilitate the transition. This mode can be referred to as Non-Stand-Alone (NSA) operation or E-UTRAN New Radio-Dual Connectivity (EN-DC) and involves both 4G and 5G carriers being simultaneously transmitted from a user equipment (UE).

In certain EN-DC applications, dual connectivity NSA involves overlaying 5G systems onto an existing 4G core network. For dual connectivity in such applications, the control and synchronization between the base station and the UE can be performed by the 4G network while the 5G network is a complementary radio access network tethered to the 4G anchor. The 4G anchor can connect to the existing 4G network with the overlay of 5G data/control.

FIG. 4 is a schematic diagram of an example dual connectivity network topology. This architecture can leverage LTE legacy coverage to ensure continuity of service delivery and the progressive rollout of 5G cells. A UE 2 can simultaneously transmit dual uplink LTE and NR carrier. The UE 2 can transmit an uplink LTE carrier Tx1 to the CNB 11 while transmitting an uplink NR carrier Tx2 to the gNB 12 to implement dual connectivity. Any suitable combination of uplink carriers Tx1, Tx2 and/or downlink carriers Rx1, Rx2 can be concurrently transmitted via wireless links in the example network topology of FIG. 4. The eNB 11 can provide a connection with a core network, such as an Evolved Packet Core (EPC) 14. The gNB 12 can communicate with the core network via the eNB 11. Control plane data can be wireless communicated between the UE 2 and eNB 11. The eNB 11 can also communicate control plane data with the gNB 12. Control plane data can propagate along the paths of the dashed lines in FIG. 4. The solid lines in FIG. 4 are for data plane paths.

In the example dual connectivity topology of FIG. 4, any suitable combinations of standardized bands and radio access technologies (e.g., FDD, TDD, SUL, SDL) can be wirelessly transmitted and received. With a TDD LTE anchor point, network operation may be synchronous, in which case the operating modes can be constrained to Tx1/Tx2 and Rx1/Rx2, or asynchronous which can involve Tx1/Tx2, Tx1/Rx2, Rx1/Tx2, Rx1/Rx2. When the LTE anchor is a frequency division duplex (FDD) carrier, the TDD/FDD inter-band operation can involve simultaneous Tx1/Rx1/Tx2 and Tx1/Rx1/Rx2.

Examples of Load Modulated Power Amplifiers with Phase Compensation

A load modulated power amplifier can include a pair of amplifiers and an output balun that includes a primary winding or coil electrically connected between the outputs of the pair of amplifiers. Additionally, the secondary winding or coil of the output balun can be electrically connected between an RF output terminal and a load modulation capacitor. The load modulated power amplifier can be used to amplify an RF input signal, and the capacitance value of the load modulation capacitor can be dynamically controlled based on the input waveform to provide load modulation.

Thus, a load modulated power amplifier can operate based on dynamically varying a load modulation capacitor connected at the secondary coil of the output balun as a function of the input waveform. Additionally, dynamically varying the capacitance value causes the differential output impedance seen by the pair of amplifiers to change according to the input waveform. For saturated power levels, the impedance of the power amplifier's load line is sufficiently low to deliver saturated output power, while for backed-off power levels the load line impedance increases dynamically so that the power amplifier still operates efficiently at reduced power.

Such a load modulated power amplifier can provide low amplitude distortion (AMAM) and good power added efficiency (PAE). However, such a load modulated power amplifier can suffer from phase distortion (AMPM) due to the capacitance value of the load modulation capacitor dynamically changing over time. For example, while the AMAM curves of the load modulated power amplifier can have positive gain dispersion, the AMPM curves can have negative phase dispersion that leads to an abrupt AMPM roll-off as the power amplifier traverses power levels along an isogain trajectory.

The AMPM roll-off of the load modulated power amplifier leads to an increase in-band adjacent channel leakage ratio (ACLR), out-of-band spectral emissions, and/or receive-band noise. Although digital pre-distortion (DPD) can be applied to the RF signal provided to the load modulated power amplifier, noise and/or emissions remain high due to limitations in DPD algorithms. For example, DPD coefficients applied to address in-band AMPM may not be available to address out-of-band spectral emission and/or receive-band noise due limitations in the DPD system's sampling frequency. In such cases, the control voltage profile for controlling the load modulation capacitor can be smoothed to lessen the abrupt transition of the AMPM profile, but smoothing the profile in this manner may degrade PAE and/or add system level complexity.

Load modulated power amplifiers with phase compensation are disclosed herein. In certain embodiments, a load modulated power amplifier receives an RF signal at an input terminal and provides an amplified RF signal at an output terminal. The load modulated power amplifier includes a load modulation capacitor, a pair of amplifiers, an output balun having a primary winding connected between the outputs of the pair of amplifiers and a secondary winding connected between the RF output terminal and the load modulation capacitor, and a load modulation control amplifier that controls a capacitance value of the load modulation capacitor based on an envelope of the RF signal. The load modulated power amplifier further includes a phase modulation capacitor connected along an RF signal path between the input terminal and the output terminal and a phase modulation control amplifier that controls a capacitance value of the phase modulation capacitor to provide phase compensation.

By implementing the load modulated power amplifier in this manner, phase distortion is compensated for. For example, as the load modulator capacitance increases the phase modulation capacitance can be decreased. Accordingly, a phase lag arising from the load modulator capacitor can be compensated for by a phase lead from the phase modulation capacitor.

The phase modulation capacitor can be positioned in a wide variety of positions along the RF signal path through the load modulated power amplifier. In one example, the phase modulation capacitor is placed at an output of a driver amplifier that drives an input balun coupled to the inputs of the pair of amplifiers. However, other positions of the phase modulation capacitor are possible, including, but not limited to, across the inputs of the pair of amplifiers, across the outputs of the pair of amplifiers, across a winding of the output balun, and/or at an input of the driver amplifier. A phase modulation capacitor is also referred to herein as a phase compensation capacitor.

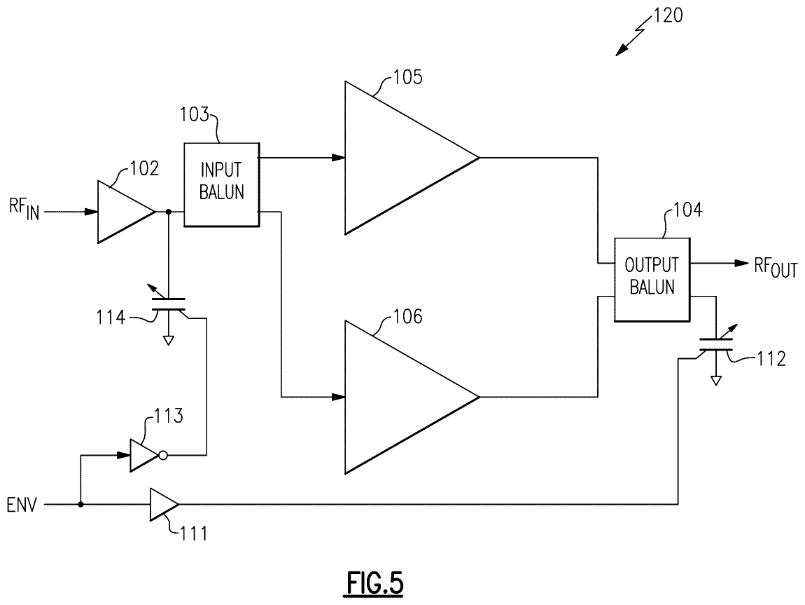

FIG. 5 is a schematic diagram of a load modulated power amplifier 120 with phase compensation according to one embodiment. The load modulated power amplifier 120 includes a driver amplifier 102, an input balun 103, an output balun 104, a first amplifier 105, a second amplifier 106 (the first amplifier 105 and the second amplifier 106 are collectively referred to herein as a pair of amplifiers), a load modulation control amplifier 111, a controllable load modulation capacitor 112, a phase modulation control amplifier 113, and a controllable phase modulation capacitor 114.

As shown in FIG. 5, the load modulated power amplifier 120 includes an input terminal that receives an RF input signal RF_{IN} and an output terminal that outputs an RF output signal RF_{OUT} corresponding to an amplified version of the RF input signal RF_{IN}.

In the illustrated embodiment, the driver amplifier 102 includes an input electrically connected to the input terminal and an output electrically connected to a first winding of the input balun 103. Additionally, a second winding of the input balun 103 is electrically connected between an input of the first amplifier 105 and an input of the second amplifier 106. Furthermore, a first winding of the output balun 104 is electrically connected between an output of the first amplifier 105 and an output of the second amplifier 106. The input balun 103, the pair of amplifiers 105/106, and the output balun 104 are arranged in a push-pull configuration, in this embodiment.

As shown in FIG. 5, a second winding of the output balun 104 is electrically connected between the output terminal and a first end of the load modulation capacitor 112. Additionally, a second end of the load modulation capacitor 112 is electrically connected to a reference voltage (corresponding to a ground voltage or ground, in this example). The phase modulation capacitor 114 is electrically connected between the output of the driver amplifier 102 and the reference voltage.

With continuing reference to FIG. 5, the load modulation control amplifier 111 controls the capacitance value of the load modulation capacitor 112 based on an envelope signal ENV indicating an envelope of the RF input signal RF_{IN}. Thus, the capacitance value of the load modulation control amplifier 111 is dynamically controlled to provide load modulation.

To compensate for phase distortion arising from the load modulation, the phase modulation control amplifier 113 and the controllable phase modulation capacitor 114 have been included.

As shown in FIG. 5, the operation of the phase modulation control amplifier 113 is inverted relative to the operation of the load modulation control amplifier 111. For example, the phase modulation control amplifier 113 provides a control signal inversion relative to the load modulation control amplifier 111. Thus, the capacitance control of the phase modulation capacitor 114 can be controlled based on the envelope signal ENV but in an opposition polarity or fashion relative to the load modulation capacitor 112.

As the load modulation capacitor 112 is dynamically controlled to provide load modulation, a real part of the differential impedance seen at the first or primary side of the output balun 104 modulates the phase to cause negative phase dispersion. Absent compensation, the negative phase dispersion leads to AMPM collapse.

However, as shown in FIG. 5, the phase modulation control amplifier 113 and the controllable phase modulation capacitor 114 have been included to provide phase compensation. For example, as the load modulator capacitance increases the phase modulation capacitance can be decreased, and thus a phase lag arising from the load modulator capacitor 112 can be compensated for by a phase lead from the phase modulation capacitor 114.

In the illustrated embodiment, the phase modulation capacitor 114 is positioned at the output of the driver amplifier 102 (for instance, at a collector in a bipolar transistor implementation or at a drain in a field-effect transistor implementation). Such a configuration is advantageous for providing timing alignment by limiting the timing delay between the load modulator capacitor 112 and the phase modulation capacitor 114 to a delay through the pair of amplifiers 105/106 which can be, for example, less than 0.2 ns.

However, other placements of the phase modulation capacitor 114 are possible.

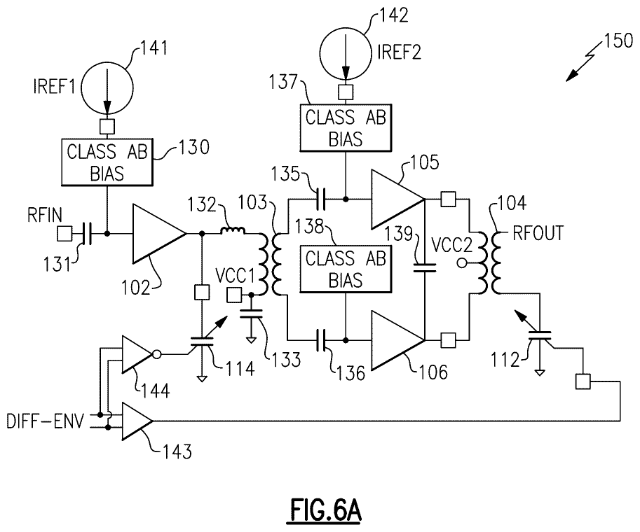

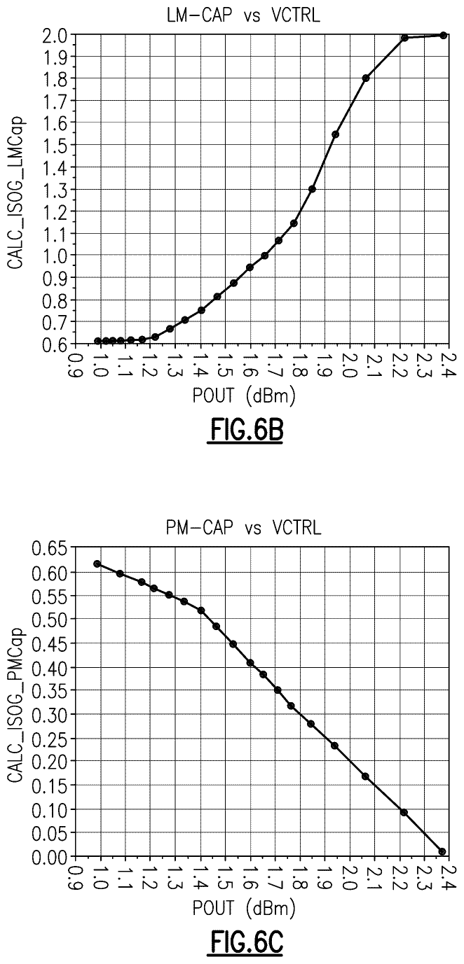

FIG. 6A is a schematic diagram of a load modulated power amplifier 150 with phase compensation according to another embodiment. The load modulated power amplifier 150 includes a driver amplifier 102, an input balun 103, an output balun 104, a first amplifier 105, a second amplifier 106, a controllable load modulation capacitor 112, a controllable phase modulation capacitor 114, a driver stage class AB bias circuit 130, a DC blocking capacitor 131, an inductor 132, a termination capacitor 133, a first input capacitor 135, a second input capacitor 136, a first output stage class AB bias circuit 137, a second output stage class AB bias circuit 138, an output capacitor 139, a first reference current source 141 (providing a current IREF1), a second reference current source 142 (providing a current IREF2), a differential-to-single-ended load modulation control amplifier 143, and a differential-to-single ended phase modulation control amplifier 144.

The load modulated power amplifier 150 of FIG. 6A is similar to the load modulated power amplifier 120 of FIG. 5, except that load modulated power amplifier 150 includes additional components and circuitry related to biasing, termination, and other amplifier performance characteristics. For example, various class AB bias circuits are depicted for biasing. Additionally, a first power supply voltage VCC1 is provided to the primary side of input balun 103 and a second power supply voltage VCC2 is provided to a center tap of the primary side of the output balun 104. Furthermore, inductor and capacitor components are depicted for various functions such as DC blocking and termination.

In the illustrated embodiment, a differential envelope signal (DIFF-ENV) is differential and is provided to the differential-to-single-ended load modulation control amplifier 143 and the differential-to-single ended phase modulation control amplifier 144. By using a differential envelope signal, enhanced immunity to common-mode noise can be achieved.

FIG. 6B is a graph of one example of control voltage for a load modulation capacitor versus output power. FIG. 6C is a graph of one example of control voltage for a phase modulation capacitor versus output power.

The graphs of FIGS. 6B and 6C depict example control voltages that can be provided to a load modulation capacitor and a phase modulation capacitor of a load modulated power amplifier with phase compensation. In the depicted example, the control voltage to the load modulation capacitor monotonically increases with signal power while the control voltage to the phase modulation capacitor monotonically decreases with signal power. Thus, a phase lag arising from the load modulator capacitor can be compensated for by a phase lead from the phase modulation capacitor.

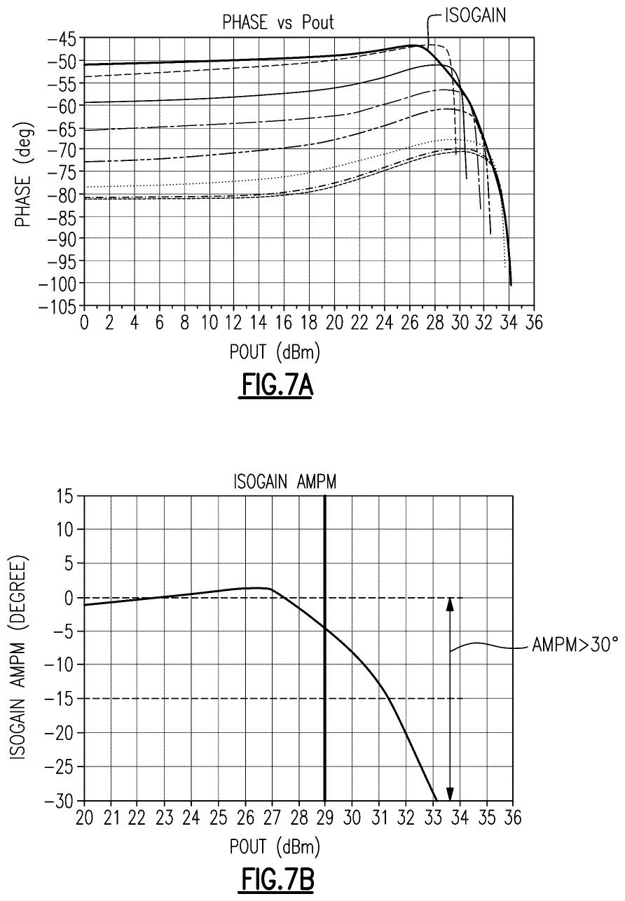

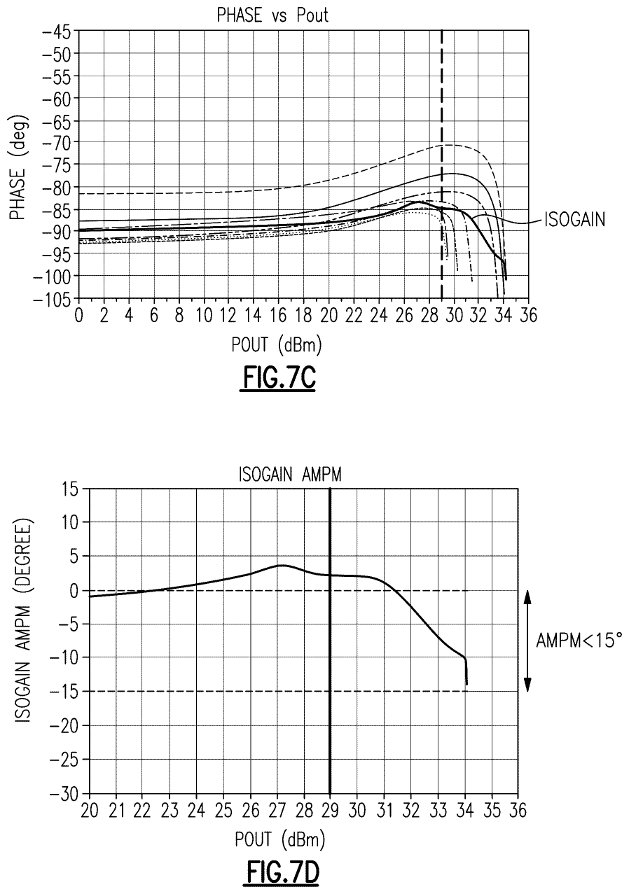

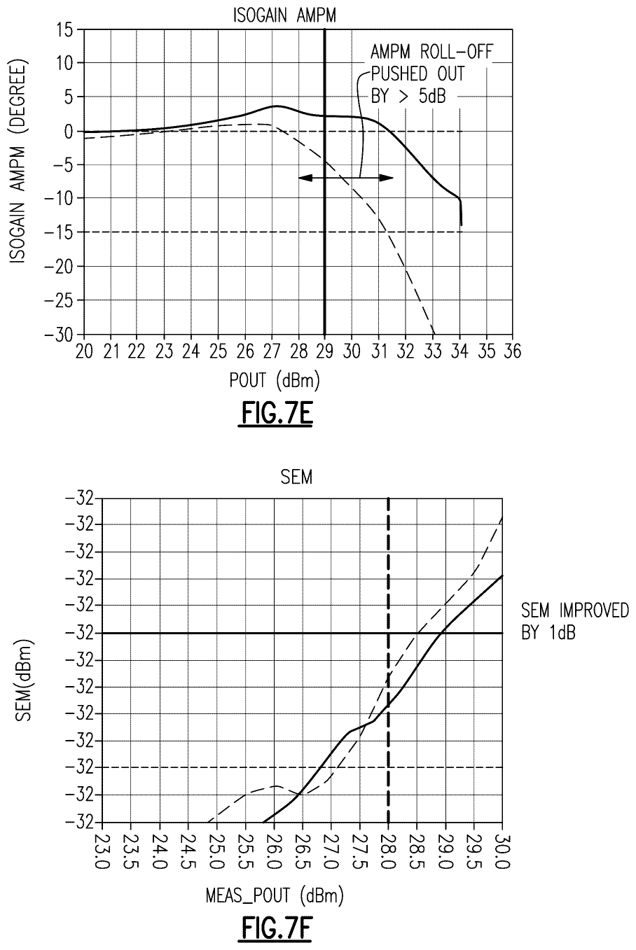

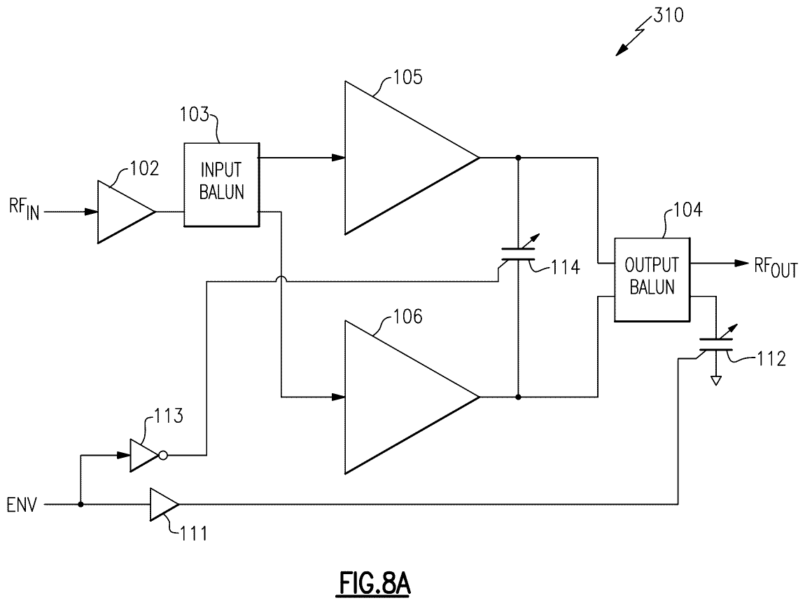

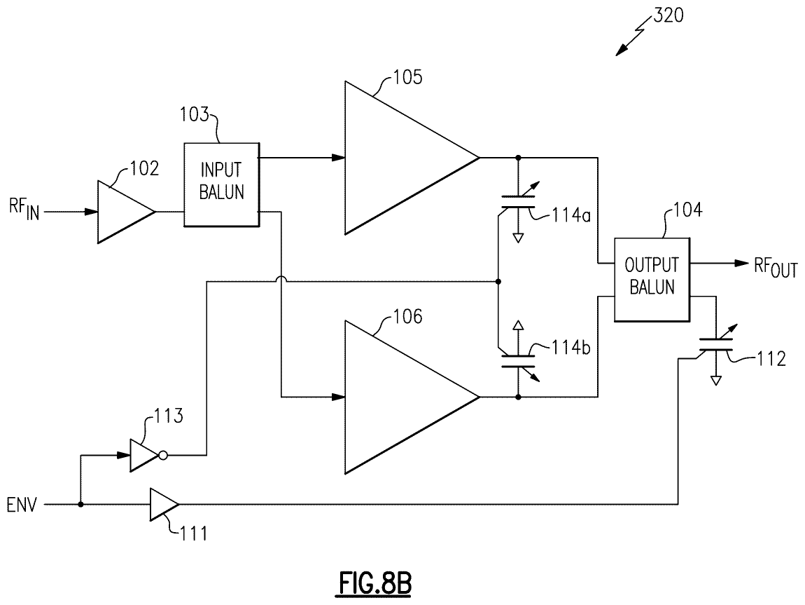

FIG. 7A is a graph of one example of phase versus output power for a load modulated power amplifier without phase compensation. FIG. 7B is a graph of one example of phase distortion versus output power for a load modulated power amplifier without phase compensation.

With reference to FIGS. 7A and 7B, load modulation causes a phase variation that causes negative phase dispersion in AMPM as shown in FIG. 7A and an AMPM collapse for isogain as shown in FIG. 7B.

FIG. 7C is a graph of one example of phase versus output power for a load modulated power amplifier with phase compensation. FIG. 7D is a graph of one example of phase distortion versus output power for a load modulated power amplifier with phase compensation. FIG. 7E is a comparison of the phase distortion characteristics of FIGS. 7B and 7D.

With reference to FIGS. 7C-7E, the phase compensation provides positive phase dispersion. The resultant AMPM trajectory for isogain shown in FIG. 7D shows a much smoother AMPM profile relative to the example of FIG. 7B. For example, the AMPM trajectory remains flat to a much higher power level (roll-off pushed out by about 5 dB) and a smoother AMPM roll-off at higher power level. Moreover, the absolute phase variation in FIG. 7D is less than 15 degrees, while the absolute phase variation in FIG. 7B is greater than 30 degrees.

FIG. 7F is a graph of one example of a comparison of spectral emissions (SEM) versus output power for a load modulated power amplifier with and without phase compensation. As shown in FIG. 7F, spectral emissions are improved by about 1 dB using phase compensation.

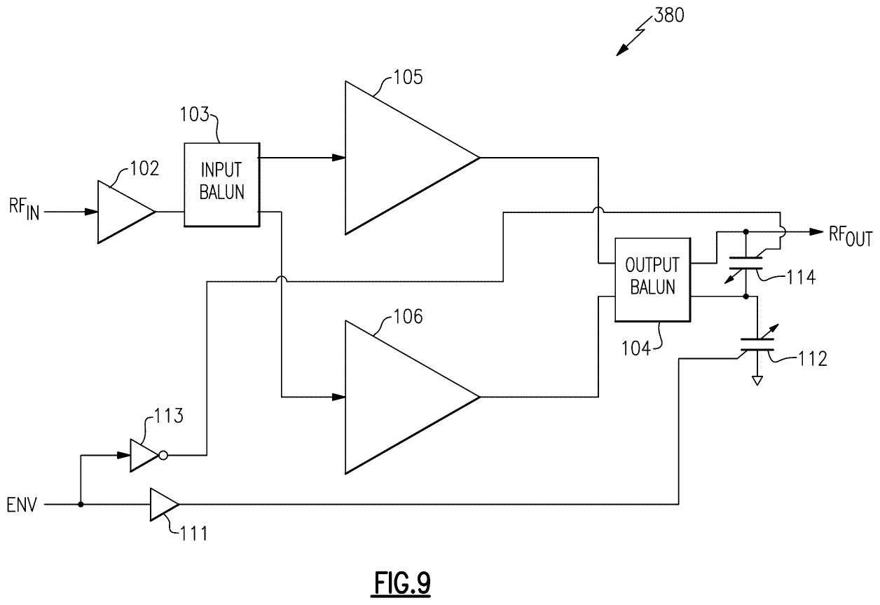

FIG. 8A is a schematic diagram of a load modulated power amplifier 310 with phase compensation according to another embodiment. The load modulated power amplifier 310 includes a driver amplifier 102, an input balun 103, an output balun 104, a first amplifier 105, a second amplifier 106, a load modulation control amplifier 111, a controllable load modulation capacitor 112, a phase modulation control amplifier 113, and a controllable phase modulation capacitor 114.

The load modulated power amplifier 310 of FIG. 8A is similar to the load modulated power amplifier 120 of FIG. 5, except that the load modulated power amplifier 310 is implemented with a different placement of the phase modulation capacitor 114. For example, in the illustrated embodiment the phase modulation capacitor 114 is electrically connected between the output of the first amplifier 105 and the output of the second amplifier 106.

The phase modulation capacitors herein can be positioned in a variety of locations along an RF signal path through a load modulated power amplifier.

FIG. 8B is a schematic diagram of a load modulated power amplifier 320 with phase compensation according to another embodiment. The load modulated power amplifier 320 includes a driver amplifier 102, an input balun 103, an output balun 104, a first amplifier 105, a second amplifier 106, a load modulation control amplifier 111, a controllable load modulation capacitor 112, a phase modulation control amplifier 113, a first controllable phase modulation capacitor 114a, and a second controllable phase modulation capacitor 114b.

The load modulated power amplifier 320 of FIG. 8B is similar to the load modulated power amplifier 310 of FIG. 8A, except that the load modulated power amplifier 320 implements the phase modulation capacitor 114 using two separate capacitors. For example, rather than connecting the phase modulation capacitor 114 across the outputs of amplifiers 105/106 as in FIG. 8A, the first phase modulation capacitor 114a is electrically connected between the output of the first amplifier 105 and ground and the second phase modulation capacitor 114b is electrically connected between the output of the second amplifier 106 and ground.

To provide phase compensation at a differential signal point along the RF signal path, a phase modulation capacitor can be placed across the differential signal point or a pair of single-ended phase modulation capacitors can be used.

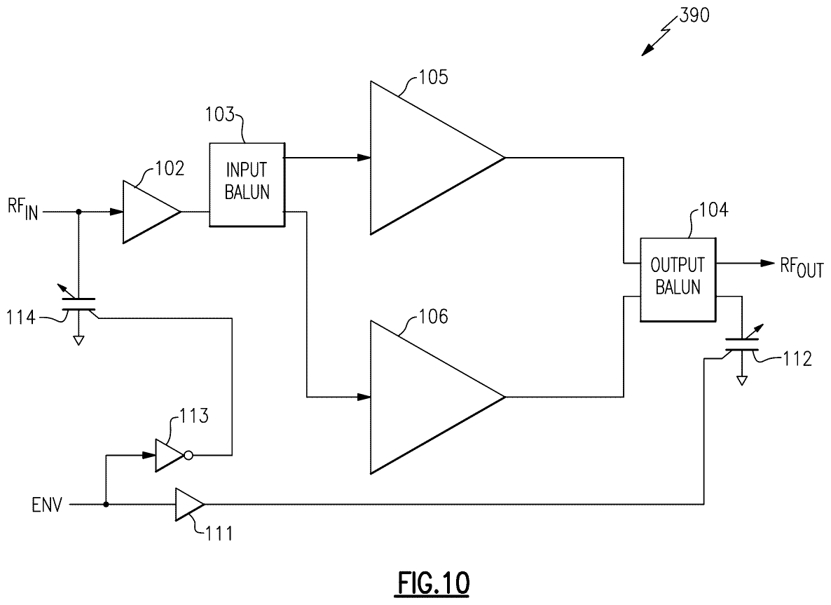

FIG. 9 is a schematic diagram of a load modulated power amplifier 330 with phase compensation according to another embodiment. The load modulated power amplifier 330 includes a driver amplifier 102, an input balun 103, an output balun 104, a first amplifier 105, a second amplifier 106, a load modulation control amplifier 111, a controllable load modulation capacitor 112, a phase modulation control amplifier 113, and a controllable phase modulation capacitor 114.

The load modulated power amplifier 330 of FIG. 9 is similar to the load modulated power amplifier 120 of FIG. 5, except that the load modulated power amplifier 310 includes a different placement of the phase modulation capacitor 114. For example, in the illustrated embodiment the phase modulation capacitor 114 is electrically connected across the secondary winding of the output balun 104. Thus, a first end of the phase modulation capacitor 114 is electrically connected to the output terminal and a second end of the phase modulation capacitor is electrically connected to the first end of the load modulation capacitor 112.

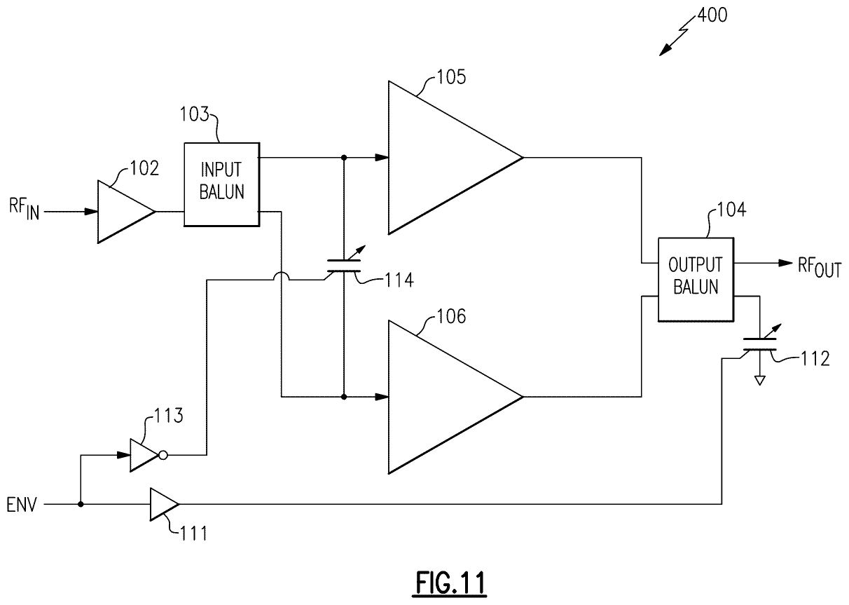

FIG. 10 is a schematic diagram of a load modulated power amplifier 390 with phase compensation according to another embodiment. The load modulated power amplifier 390 includes a driver amplifier 102, an input balun 103, an output balun 104, a first amplifier 105, a second amplifier 106, a load modulation control amplifier 111, a controllable load modulation capacitor 112, a phase modulation control amplifier 113, and a controllable phase modulation capacitor 114.

The load modulated power amplifier 390 of FIG. 10 is similar to the load modulated power amplifier 120 of FIG. 5, except that the load modulated power amplifier 310 includes a different placement of the phase modulation capacitor 114. For example, in the illustrated embodiment the phase modulation capacitor 114 is electrically connected between the input of the driver amplifier 102 and ground.

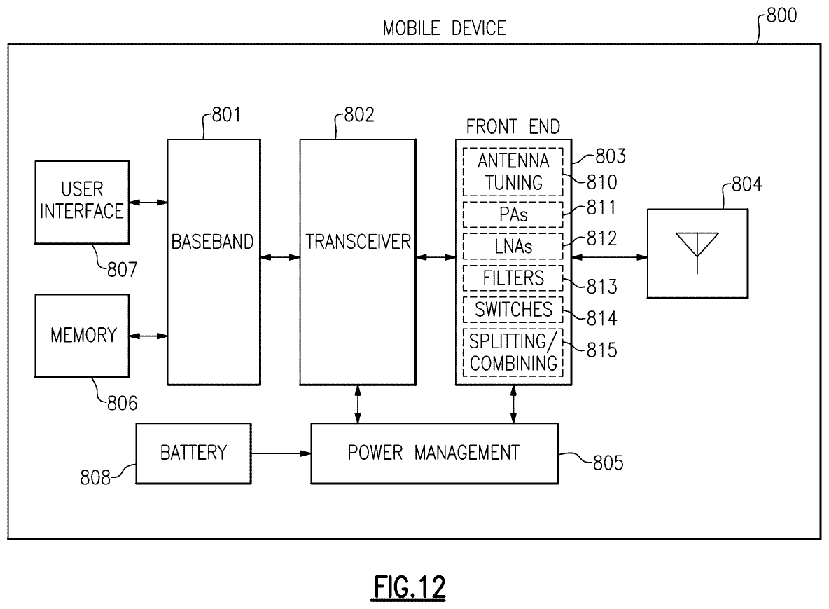

FIG. 11 is a schematic diagram of a load modulated power amplifier 400 with phase compensation according to another embodiment. The load modulated power amplifier 400 includes a driver amplifier 102, an input balun 103, an output balun 104, a first amplifier 105, a second amplifier 106, a load modulation control amplifier 111, a controllable load modulation capacitor 112, a phase modulation control amplifier 113, and a controllable phase modulation capacitor 114.

The load modulated power amplifier 400 of FIG. 11 is similar to the load modulated power amplifier 120 of FIG. 5, except that the load modulated power amplifier 400 includes a different placement of the phase modulation capacitor 114. For example, in the illustrated embodiment the phase modulation capacitor 114 is electrically connected across the inputs of the pair of amplifiers 105/106.

FIG. 12 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. In transceiver 802 can also generate other signals, such as an envelope signal indicating the envelope of an RF signal to be transmitted. A transceiver is also referred to herein as a radio frequency integrated circuit (RFIC).

It will be understood that various functionalities associated with the transmission and receiving of RF signals can be achieved by one or more components that are collectively represented in FIG. 12 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAS) 811, low noise amplifiers (LNAs) 812, filters 813, switches 814, and signal splitting/combining circuitry 815. However, other implementations are possible. One or more of the PAs 811 can include a load modulated power amplifier implemented in accordance with the teachings herein.

The front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD) and may be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 12, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 12, the power management system 805 receives a battery voltage from the battery 808. The battery 808 can be any suitable battery for use in the mobile device 800, including, for example, a lithium-ion battery.

### Applications

Some of the embodiments described above have provided examples in connection with mobile devices. However, the principles and advantages of the embodiments can be used for any other systems or apparatus that have needs for load modulated power amplifiers. Examples of such systems or apparatus include, but are not limited to, mobile phones, tablets, base stations, network access points, customer-premises equipment (CPE), laptops, and wearable electronics.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A mobile device comprising:
a transceiver configured to generate a radio frequency signal; and
a front-end system including a load modulated power amplifier having an input terminal configured to receive the radio frequency signal and an output terminal configured to provide an amplified radio frequency signal, the load modulated power amplifier including a load modulation capacitor, a first amplifier, a second amplifier, an output balun having a first winding electrically connected between an output of the first amplifier and an output of the second amplifier and a second winding electrically connected between the output terminal and the load modulation capacitor, a load modulation control amplifier configured to control a capacitance value of the load modulation capacitor based on an envelope of the radio frequency signal, a phase modulation capacitor connected along a radio frequency signal path between the input terminal and the output terminal, and a phase modulation control amplifier configured to control a capacitance value of the phase modulation capacitor to provide phase compensation.

2. The mobile device of claim 1 wherein the load modulation control amplifier increases the capacitance value of the load modulation capacitor in response to an increase in a power level of the radio frequency signal, and the phase modulation control amplifier decreases the capacitance value of the phase modulation capacitor in response to the increase in the power level.

3. The mobile device of claim 1 wherein the load modulation control amplifier and the phase modulation control amplifier are controlled based on the envelope of the radio frequency signal, the phase modulation control amplifier providing an inversion relative to the load modulation control amplifier.

4. The mobile device of claim 3 wherein the load modulation control amplifier and the phase modulation control amplifier are each differential-to-single ended amplifiers receiving a differential envelope signal indicating the envelope of the radio frequency signal.

5. The mobile device of claim 1 wherein a control voltage outputted from the load modulation control amplifier monotonically increases with a power level of the radio frequency signal, and a control voltage outputted from the phase modulation control amplifier monotonically decreases with the power level of the radio frequency signal.

6. The mobile device of claim 1 wherein the load modulated power amplifier further includes a driver amplifier and an input balun having a first winding electrically connected to an output of the driver amplifier and a second winding electrically connected between an input of the first amplifier and an input of the second amplifier.

7. The mobile device of claim 6 wherein the phase modulation capacitor is electrically connected between an output of the driver amplifier and a reference voltage.

8. The mobile device of claim 6 wherein the phase modulation capacitor is electrically connected between an input of the driver amplifier and a reference voltage.

9. The mobile device of claim 1 wherein the phase modulation capacitor is electrically connected to at least one of an input of the first amplifier or an input of the second amplifier.

10. The mobile device of claim 1 wherein the phase modulation capacitor is electrically connected to at least one of the output of the first amplifier or the output of the second amplifier.

11. The mobile device of claim 1 wherein the phase modulation capacitor is electrically connected to the second winding of the output balun.

12. The mobile device of claim 1 wherein the first amplifier and the amplifier are arranged as a pair of amplifiers in a push-pull configuration.

13. A load modulated power amplifier comprising:
an input terminal configured to receive a radio frequency signal and an output terminal configured to provide an amplified radio frequency signal;
a load modulation capacitor;
a pair of amplifiers including a first amplifier and a second amplifier;
an output balun having a first winding electrically connected between an output of the first amplifier and an output of the second amplifier and a second winding electrically connected between the output terminal and the load modulation capacitor;
a load modulation control amplifier configured to control a capacitance value of the load modulation capacitor based on an envelope of the radio frequency signal;
a phase modulation capacitor connected along a radio frequency signal path between the input terminal and the output terminal; and
a phase modulation control amplifier configured to control a capacitance value of the phase modulation capacitor to provide phase compensation.

14. The load modulated power amplifier of claim 13 wherein the load modulation control amplifier increases the capacitance value of the load modulation capacitor in response to an increase in a power level of the radio frequency signal, and the phase modulation control amplifier decreases the capacitance value of the phase modulation capacitor in response to the increase in the power level.

15. The load modulated power amplifier of claim 13 wherein the load modulation control amplifier and the phase modulation control amplifier are controlled based on the envelope of the radio frequency signal, the phase modulation control amplifier providing an inversion relative to the load modulation control amplifier.

16. The load modulated power amplifier of claim 13 wherein a control voltage outputted from the load modulation control amplifier monotonically increases with a power level of the radio frequency signal, and a control voltage outputted from the phase modulation control amplifier monotonically decreases with the power level of the radio frequency signal.

17. The load modulated power amplifier of claim 13 further comprising a driver amplifier and an input balun having a first winding electrically connected to an output of the driver amplifier and a second winding electrically connected between an input of the first amplifier and an input of the second amplifier, the phase modulation capacitor electrically connected between an output of the driver amplifier and a reference voltage.

18. The load modulated power amplifier of claim 13 wherein the phase modulation capacitor is electrically connected to at least one of an input of the first amplifier or an input of the second amplifier.

19. The load modulated power amplifier of claim 13 wherein the phase modulation capacitor is electrically connected to at least one of the output of the first amplifier or the output of the second amplifier.

20. A method of amplification in a load modulated power amplifier, the method comprising:
receiving a radio frequency signal at an input terminal and outputting an amplified radio frequency signal from an output terminal;
controlling a capacitance value of a load modulation capacitor coupled to an output balun based on an envelope of the radio frequency signal using a load modulation control amplifier, the output balun having a first winding electrically connected between an output of a first amplifier and an output of a second amplifier and a second winding electrically connected between the output terminal and the load modulation capacitor; and
controlling a capacitance value of a phase modulation capacitor to provide phase compensation using a phase modulation control amplifier, the phase modulation capacitor connected along a radio frequency signal path between the input terminal and the output terminal.
